(19) United States
(12) Patent Application Publication
(10) Pub. No.: US 2014/0299831 A1
(43) Pub. Date: Oct. 9, 2014

(54) 3D VARIABLE RESISTANCE MEMORY DEVICE AND METHOD OF MANUFACTURING THE SAME

(71) Applicant: SK HYNIX INC., Gyeonggi-do (KR)

(72) Inventor: Nam Kyun PARK, Gyeonggi-do (KR)

(73) Assignee: SK HYNIX INC., Gyeonggi-do (KR)

(21) Appl. No.: 13/950,572

(22) Filed: Jul. 25, 2013

(30) Foreign Application Priority Data
Apr. 9, 2013 (KR) 10-2013-0038586

(51) Int. Cl. H01L 27/24; H01L 29/66; H01L 21/822; H01L 45/00

(52) U.S. Cl. CPC H01L 27/2454; H01L 45/16; H01L 27/2481; H01L 29/66666; H01L 21/8221
USPC 257/4; 438/238

(57) ABSTRACT

A 3D variable resistance memory device and a method of manufacturing the same are provided. A semiconductor substrate includes a peripheral area, having a top surface, wherein a peripheral circuit is formed in the peripheral area. The peripheral circuit includes a driving transistor formed on a surface of the semiconductor substrate, wherein the semiconductor substrate forms the channel of the driving transistor. The semiconductor substrate includes a cell area, having a top surface, wherein a height of the top surface of the cell area is lower than a height of the top surface of the peripheral area, thereby defining a trench in the cell area. A plurality of memory cells, each include a switching transistor formed on the semiconductor substrate in the cell area, a channel extending in a direction substantially perpendicular to a surface of the semiconductor substrate, and a variable resistance layer that selectively stores data in response to the switching transistor.

### CROSS-REFERENCES TO RELATED APPLICATION

The present application claims priority under 35 U.S.C. 19(a) to Korean application number 10-2013-0038586, filed on Apr. 9,2013, in the Korean Intellectual Property Office, which is incorporated herein by reference in its entirety.

### BACKGROUND

1. Technical Field

The inventive concept relates to a semiconductor integrated circuit device and a method of manufacturing the same, and more particularly, to a three-dimensional (3D) variable resistance memory device and a method of manufacturing the same.

2. Related Art

Memory devices are generally provided as internal semiconductor integrated circuits of computers or other electronic apparatuses. The memory devices are divided into volatile memory devices and nonvolatile memory devices. In recent years, variable resistance memory devices have been more closely studied.

Examples of variable resistance memory devices include phase-change random access memory devices (PCRAMs), resistive RAMS (ReRAMs), and magnetic RAMS (MRAMs). Among the variable resistance memory devices, the PCRAMs have characteristics such as high memory density like dynamic random access memories (DRA high reliability, and low power consumption.

The nonvolatile memory devices, including the variable resistance memory devices, may be used in portable music players such as MP3 players, movie players, or other electronic apparatuses, portable phones, digital cameras, solid states drives (SSDs), portable memory sticks, or personal computers.

The variable resistance memory devices may include a plurality of memory cells arranged in a matrix form. Each of the plurality of memory cells may include a switching device connected to a word line and a resistance device connected to a bit line.

The switching device may be accessed by activating a corresponding word line. The selected memory cell may programmed by a current transferred to the resistance device.

To achieve a high integration density and multi-level cell, the switching device of the variable resistance memory device may have a 3D structure and the resistance device is stacked on the switching device. [Unclear.]

As is generally known, a channel of the 3D switching device is generally extends perpendicular to a surface of a semiconductor substrate. Therefore, the 3D switching device has a narrower width and a relatively higher height than a 2D switching device.

However, in the 3D variable resistance memory devices, since a lower electrode is additionally formed on the 3D switching device having the increased height, there is difficulty in forming the lower electrode. Furthermore, a step between a cell area and a peripheral area is increased,

### SUMMARY

An exemplary variable resistance memory device may include A variable resistance memory device, comprising a semiconductor substrate including a peripheral area, having a top surface, wherein a peripheral circuit is formed in the peripheral area, the peripheral circuit including a driving transistor formed on a surface of the semiconductor substrate, wherein the semiconductor substrate forms the channel of the driving transistor, and a cell area, having a top surface, wherein a height of the top surface of the cell area is lower than a height of the top surface of the peripheral area, thereby defining a trench in the cell area; and a plurality of memory cells, each of the plurality of memory cells including a switching transistor formed on the semiconductor substrate in the cell area, a channel extending in a direction substantially perpendicular to a surface of the semiconductor substrate, and a variable resistance layer that selectively stores data in response to the switching transistor.

A method of manufacturing an exemplary variable resistance memory device may include providing a semiconductor substrate in which a cell area and a peripheral area are defined; forming a first trench in the semiconductor substrate in the cell area and a second trench in the semiconductor substrate in a device isolation region of the peripheral area; forming a device isolation layer in the second trench; forming a switching transistor in the first trench; forming a lower electrode on the switching transistor; forming a driving transistor in the peripheral area; and forming a variable resistance layer on the lower electrode.

A method of manufacturing an exemplary variable resistance memory device may include forming a trench in a cell area of a substrate; forming a vertical channel transistor in the trench; forming a lower electrode and a hard mask layer on the vertical channel transistor; forming a first insulating layer at sides of the vertical channel transistor; forming a second insulating layer at sides of the lower electrode and the hard mask layer; defining, by selectively removing the hard mask layer, a space in the second insulating layer to contain a variable resistance layer; and forming a variable resistance layer in the space to contain a variable resistance layer.

These and other features, aspects, and implementations are described below in the section entitled “DETAILED DESCRIPTION”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1 to 9 are cross-sectional views illustrating a method of manufacturing an exemplary variable resistance memory device.

### DETAILED DESCRIPTION

Hereinafter, an exemplary implementation will be described in greater detail with reference to the accompanying drawings.

An exemplary implementation is described herein with reference to cross-sectional illustrations that are schematic illustrations of the exemplary implementation (and intermediate structures). As such, variations from the shapes of the illustrations as a result, for example, of manufacturing techniques and/or tolerances, are to be expected. Thus, the exemplary implementation should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

Referring to FIG. 1, a semiconductor substrate 100, in which a cell area A and a peripheral area B are defined, is prepared. For example, the semiconductor substrate 100 may be a silicon substrate, but the semiconductor substrate 100 is not limited thereto. The semiconductor substrate 100 may include a wafer formed of any semiconductor material, such as a silicon-on-insulator (SOT) or a gallium arsenide (GaAS).

A first trench T1 is formed in the cell area A, and a second trench T2 is formed in the peripheral area B. The first trench T1 may be entirely formed in the cell area A, and the second trench T2 may be formed in a device isolation formation region of the peripheral area B. The first trench T1 and the second trench T2 may have different widths, but may have the same depth.

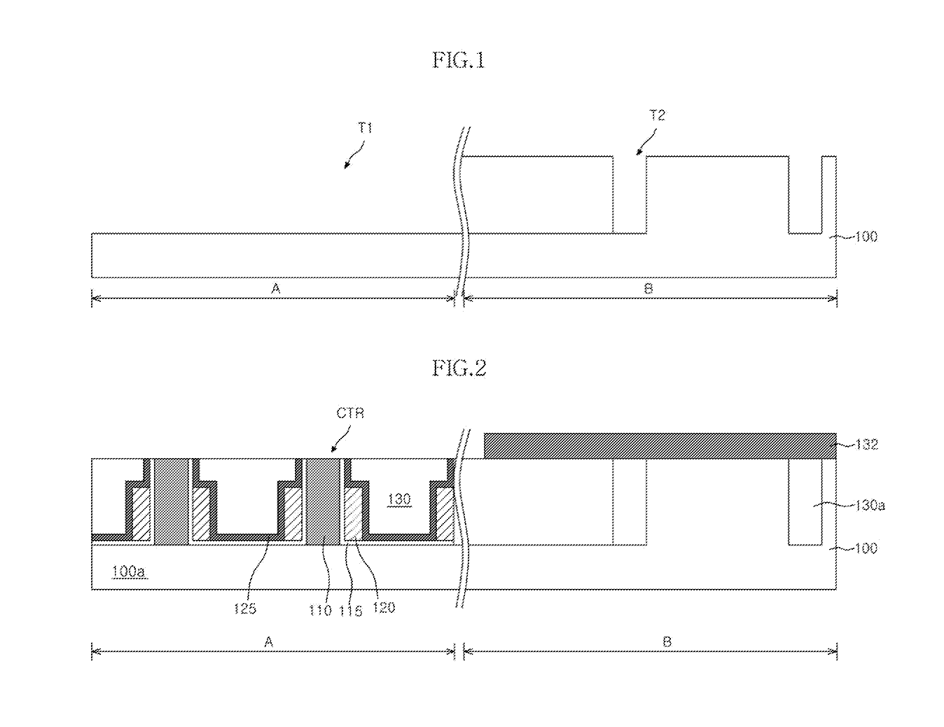

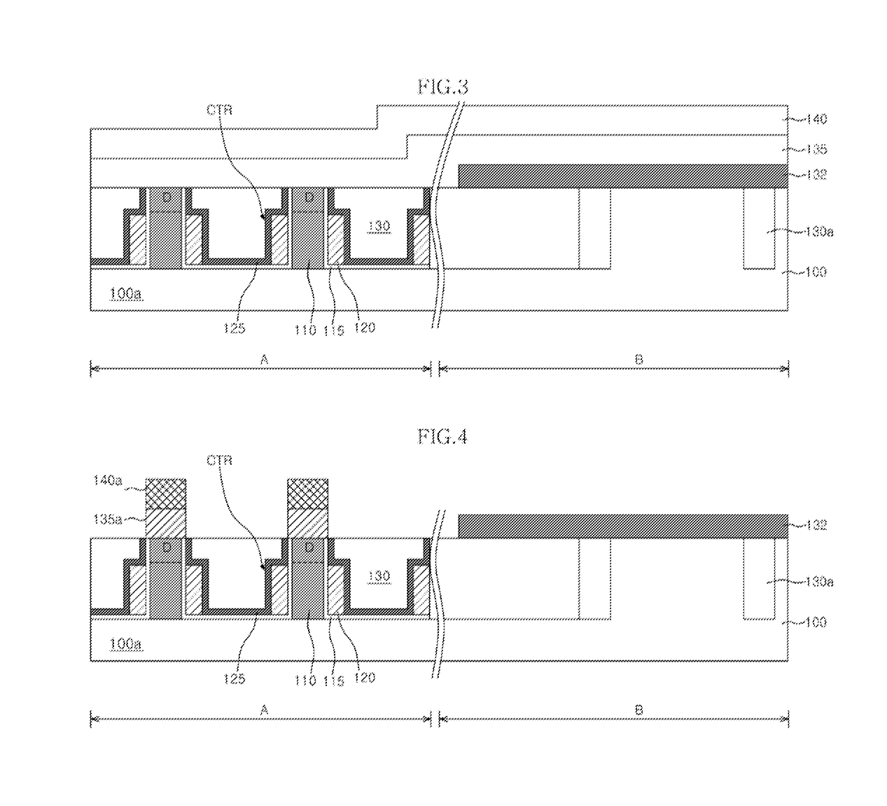

Referring to FIG. 2, a pillar 110 is formed in a predetermined region of the cell area A. The pillar 110 may be formed by depositing a semiconductor layer on the cell area A and patterning the semiconductor layer. For example, the pillar 110 may include a polysilicon layer and have substantially the same height as a depth of the trench T1. Before the formation of the pillar 110, an impurity ion implantation process is performed on a bottom of the first trench T1 so that the bottom of the first trench T1 (i.e. the semiconductor substrate 100 of the cell area A) may be used as a common source of a switching transistor to be formed later. A gate insulating layer 115 may be formed on a surface of the semiconductor substrate 100, expect for a portion of the surface of the semiconductor substrate 100 where the pillar 110 is formed, and a side of the pillar 110. For example, the gate insulating layer 115 may be formed by performing an oxidation on the semiconductor substrate 100 and the pillar 110. A gate 120 may be formed on the gate insulating layer 115 to surround the pillar 100. Hereinafter, the gate 120 will be referred to as a surround gate. For example, the surround gate 120 may include a doped polysilicon layer or a metal layer. The surround gate 120 may be formed to a height lower than that of the pillar 110 to overlap a region of the pillar 100 which is to be used as a channel. A protection layer 125, which serves as an etch stopper, may be formed on the gate insulating layer 115 and on the surround gate 120. The protection layer 125 may have a uniform thickness. An insulating layer 130 may be formed over the semiconductor substrate 100 and in the first trench T1 and the second trench T2. The semiconductor substrate 100 is then planarized to expose the semiconductor substrate 100. Therefore, the surround gate 120, formed in the cell area A, may be insulated by the insulating layer 130, and a device isolation layer 130a may be formed in the peripheral area B. A sacrificial layer 132 may be formed on the semiconductor substrate 100, in which the device isolation layer 130a may be formed. For example, the sacrificial layer 132 may include an insulating layer. The sacrificial layer 132 may be selectively removed in the cell area A, but may remain on the peripheral area B. A switching transistor CTR may be formed in the cell area A by ion-implanting an impurity to form a drain junction region into a portion of the pillar 110 exposed by the sacrificial layer 132. A drain junction region D of the switching transistor CTR is formed in an upper portion of the pillar 110.

Referring to FIG. 3, a lower electrode layer 135 and a hard mask layer 140 may be sequentially formed on the semiconductor substrate 100 and the sacrificial layer 132. The lower electrode layer 135 may include, for example, an impurity-doped polysilicon layer or a metal layer. The hard mask layer 140 may include, for example, a silicon nitride layer. If the lower electrode layer 135 includes a metal layer, then a metal silicide layer (not shown) may be selectively formed between the pillar 110 and the lower electrode layer 135. The sacrificial layer 132 may function to protect the semiconductor substrate 100 corresponding to the peripheral area B from the lower electrode layer 135.

Referring to FIG. 4, a lower electrode 135a and a hard mask 140a may be formed by patterning the lower electrode layer 135 and the hard mask layer 140.

Referring to FIG. 5, a first interlayer insulating layer 145 may be formed on the semiconductor substrate 100, over which the lower electrode 135a and the hard mask 140a are formed. The first interlayer insulating layer 145 may be formed in a space between adjacent pairs of lower electrodes 135a and hard masks 140a. The first interlayer insulating layer 145 may have a thickness substantially equal to a combined thickness of the lower electrode 135a and the hard mask 140a. The first interlayer insulating layer 145 may and then planarized to expose a surface of the hard masks 140a.

An etch stopper layer 150 is formed on the planarized first interlayer insulating layer 145. The etch stopper layer 150 may include, for example, a silicon nitride layer.

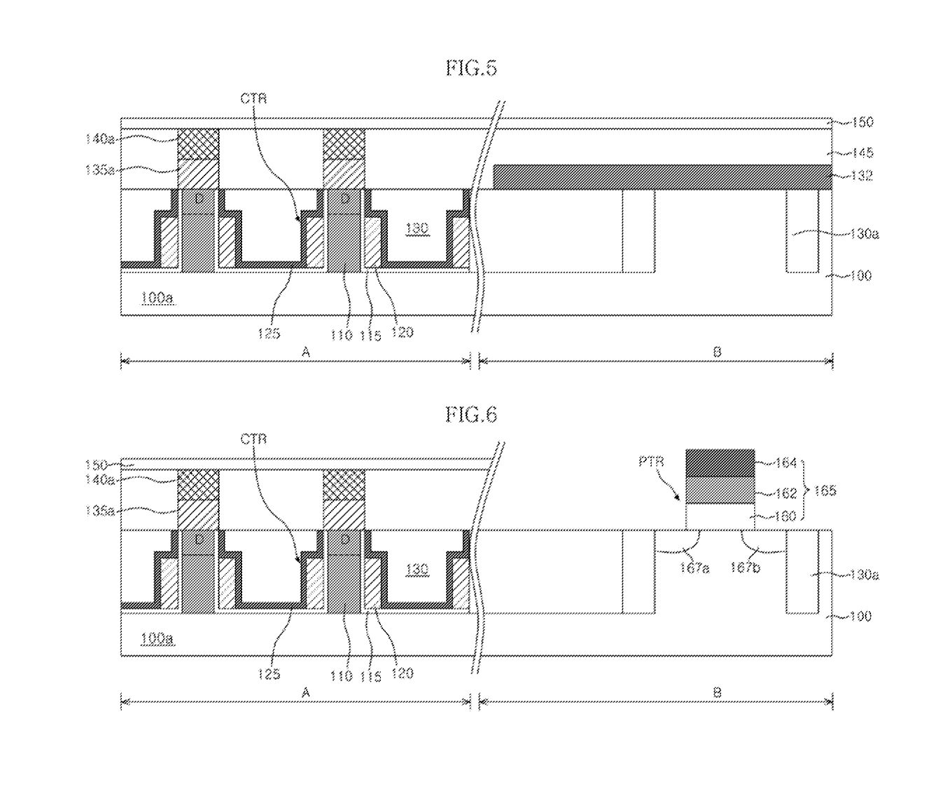

Referring to FIG. 6, the etch stopper layer 150, the first interlayer insulating layer 145, and the sacrificial layer 132 are etched to expose a surface of the semiconductor substrate 100 in the peripheral area B. A gate insulating layer [Not shown in FIG. 6], a polysilicon layer 160, a metal layer 162, and a hard mask layer 164 are sequentially stacked on an exposed active region of the peripheral area B (i.e., a region between the device isolation layers 130a). Predetermined portions of the polysilicon layer 160, the metal layer 162, and the hard mask layer 164 may be patterned to form a gate structure 165. Alternatively, the gate structure 165 may be formed of a single polysilicon layer or a single metal layer. A source 167a and a drain 167b may be formed in the active region of the peripheral area B at sides of the gate structure 165. Therefore, a driving transistor PTR may be formed in the peripheral area B. The driving transistor PTR may read and Trite data from and to memory cells formed in the cell area A.

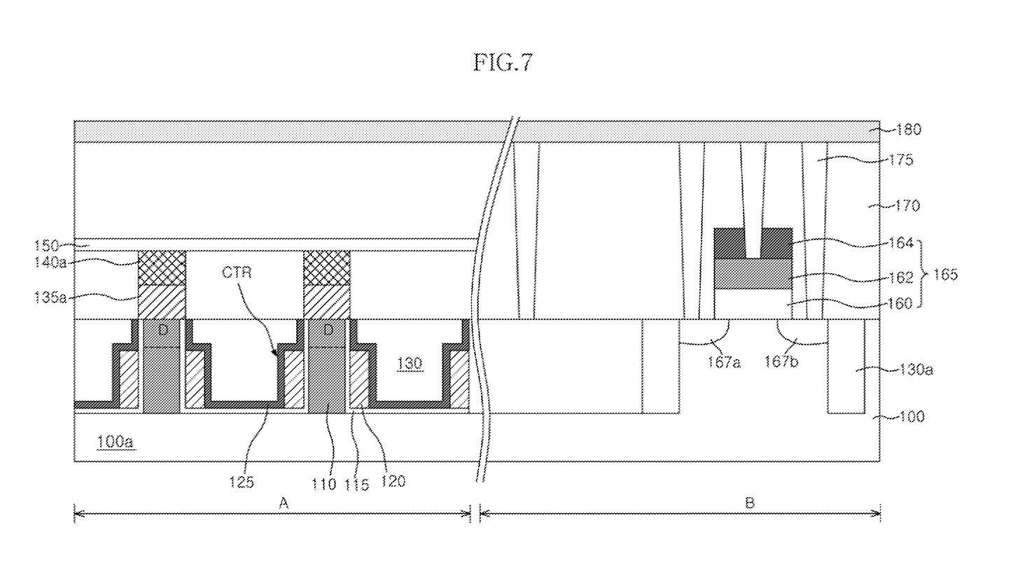

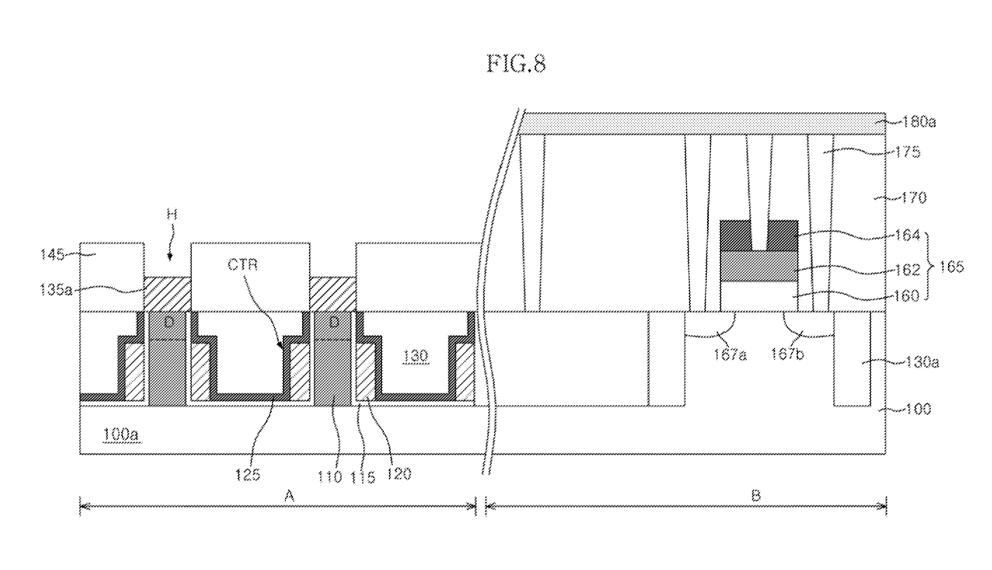

Referring to FIG. 7, a second interlayer insulating layer 170 may be formed over the semiconductor substrate 100, that is, on the entire cell area A and the entire peripheral area B. That is, the second interlayer insulating layer 170 may cover the peripheral area B and, in the cell area A, the second interlayer insulating layer 170 may cover the first interlayer insulating layer 145 and the etch stopper layer 150. The second interlayer insulating layer 170 may be planarized, Next, a conductive plug 175 may be electrically connected to a conductive region of the peripheral area B, for example, the metal layer 162, the source 167a and the drain 167b is formed in the second interlayer insulating layer 170 through a general method. For example, the conductive plug 175 may include a metal layer having a gap fill characteristic such as tungsten. However, the conductive plug 175 is not limited thereto, and various conductive materials may be used as the conductive plug. A capping layer 180 may be formed on the planarized second interlayer insulating layer 170, In the exemplary implementation, the capping layer 180 may protect device structures formed on the peripheral area B and selectively expose the etch stopper layer 150 of the cell area A (as will be described later).

Referring to FIG. 8, the capping layer 180 on the cell area A is selectively removed and remains on the peripheral area B as capping layer 180. The second interlayer insulating layer 170 on the cell area A is etched using the remaining capping layer 180 as a mask to expose the etch stopper layer 150 formed on the cell area A. Next, the exposed etch stopper layer 150 is selectively removed. Since the etch stopper layer 150 is formed of a silicon nitride layer, as described above, the etch stopper layer 150 may be selectively removed through a wet etch process. At this time, the hard mask layer 140a, which is disposed below the etch stopper layer 150 and formed of the same material as the etch stopper layer 150, may be also removed. A space H is formed by the removal of the hard mask layer 140a. A variable resistance material will be formed in the space H in a subsequent process.

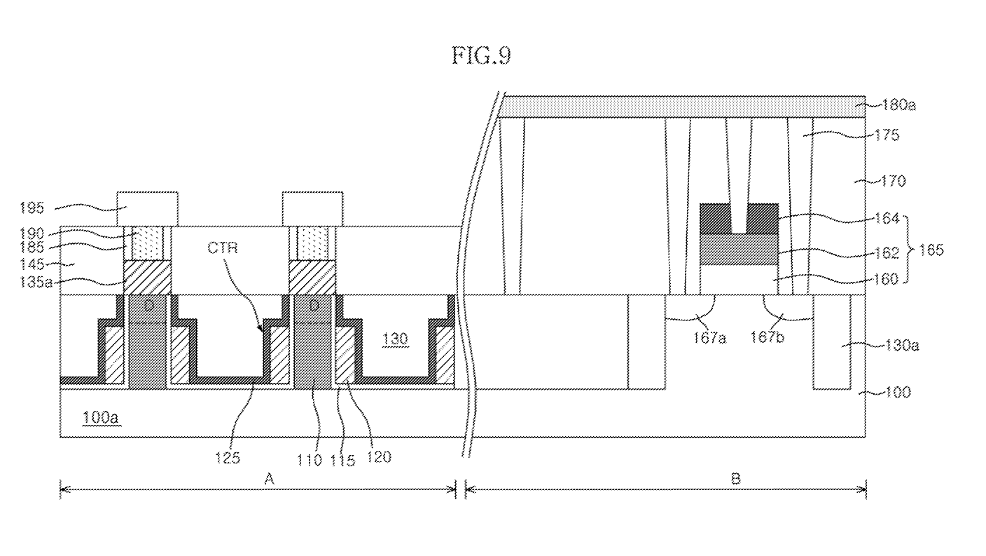

Referring to FIG. 9, a heat-resistant spacer 185 may be formed on a sidewall of the space H. The heat-resistant spacer 185 may include, for example, a silicon nitride layer. A variable resistance layer 190 may be formed in the space H and surrounded by the heat-resistant spacer 185. Characteristics of the device may be changed based on a type of material used as the variable resistance layer 190. Various materials may be used for the variable resistance layer 190. For example, a PCMO (Pr₁₋ₓCaₓMnO₃) layer may be used for a ReRAM, a chalcogenide layer may be used for a PCRAM, a magnetic layer may be used for a MRAM, a magnetization reversal device layer may be used for a spin-transfer torque magnetoresistive RAM (STTMRAM), or a polymer layer may be used a polymer RAM (PoRAM). An upper electrode 195 may be formed on the variable resistance layer 190 by a known method.

As described above, the switching transistor formed in the cell area may be formed in the trench region to reduce a step between the cell area and the peripheral area.

Further, the lower electrode may be formed before the driving transistor of the peripheral area is formed, and the space H may be formed in a self-aligning manner by removing the hard mask layer after the driving transistor is formed. Therefore, the variable resistance layer may be formed without the effect of increasing of an aspect ratio.

As described above, the spare H may be defined at the same time as the removal of the etch stopper layer formed in the cell area. Therefore a separate etching process for defining the space H is not necessary.

The above exemplary implementation is illustrative and not limitative. Various alternatives and equivalents are possible. The invention is not limited by the exemplary implementation described herein. Nor is the invention limited to any specific type of semiconductor device. Other additions, subtractions, or modifications are obvious in view of the present disclosure and are intended to fall within the scope of the appended claims.

What is claimed is:

1. A variable resistance memory device, comprising:
a semiconductor substrate including:
a peripheral area, having a top surface, wherein a peripheral circuit is formed in the peripheral area, the peripheral circuit including a driving transistor formed on a surface of the semiconductor substrate, wherein the semiconductor substrate forms the channel of the driving transistor, and
a cell area, having a top surface, wherein a height of the top surface of the cell area is lower than a height of the top surface of the peripheral area, thereby defining a trench in the cell area, and
a plurality of memory cells, each of the plurality of memory cells including:
a switching transistor formed on the semiconductor substrate in the cell area,
a channel extending in a direction substantially perpendicular to a surface of the semiconductor substrate, and
a variable resistance layer that selectively stores data in response to the switching transistor.

2. The variable resistance memory device of claim wherein the switching transistor includes:
a common source included in the cell area of the semiconductor substrate;
a pillar formed in the cell area, the pillar extending in a direction substantially perpendicular to a surface of the cell area, and having an upper portion that forms a drain junction region;
a gate formed around a circumference of the pillar, the gate having a height lower than a height of the pillar; and
a gate insulating layer interposed between the pillar and the gate.

3. The variable resistance memory device of claim 2, wherein the height of the pillar is substantially the same as the height of the top surface of the peripheral area.

4. The variable resistance memory device of claim. wherein the variable resistance layer is formed on the pillar.

5. The variable resistance memory device of claim 4, further comprising:
a lower electrode formed between the pillar and the variable resistance layer.

6. A method of manufacturing a variable resistance memory device, the method comprising:
providing a semiconductor substrate in which a cell area and a peripheral area are defined;
forming a first trench in the semiconductor substrate in the cell area and a second trench in the semiconductor substrate in a device isolation region of the peripheral area;
forming a device isolation layer in the second trench;
forming a switching transistor in the first trench;
forming a lower electrode on the switching transistor;
forming a driving transistor in the peripheral area; and
forming a variable resistance layer on the lower electrode.

7. The method of claim 6 wherein the forming the switching transistor includes:
selectively forming an insulating layer on the peripheral area in which the trench is formed;
forming a common source region n the semiconductor substrate in the first trench;
forming a pillar on the substrate in the first trench;
forming a gate insulating layer on the substrate and the pillar;
forming a gate around the pillar; and
forming a drain in an upper portion of the pillar.

8. The method of claim 6, wherein the forming the lower electrode includes:
forming a lower electrode layer and a hard mask layer over he semiconductor substrate; and
patterning the lower electrode layer and the hard mask layer to form the lower electrode on the switching transistor.

9. The method of claim 8, further comprising:
forming a first interlayer insulating layer over the cell area, the peripheral area, and the lower electrode;
forming an etch stopper layer on the first interlayer insulating layer; and
removing the etch stopper layer and the first interlayer insulating from the peripheral area.

10. The method of claim 9, further comprising:
forming a second interlayer insulating layer over the cell area and the peripheral area;
forming, in the second interlayer insulating layer formed over the peripheral area, an interconnection layer to electrically connect to the driving transistor;
forming a capping layer on the second interlayer insulating layer; and
defining a space to contain a variable resistance layer by removing the capping layer formed over the cell area, the second interlayer insulating layer formed over the cell area, the etch stopper layer formed over the cell area, and the hard mask layer formed over the cell area.

11. The method of claim 10, further comprising:
forming a variable resistance layer in the space to contain a variable resistance layer.

12. A method of manufacturing a variable resistance memory device, the method comprising:
forming a trench in a cell area of a substrate;
forming a vertical channel transistor in the trench;
forming a lower electrode and a hard mask layer on the vertical channel transistor;
forming a first insulating layer at sides of the vertical channel transistor;
forming a second insulating layer at sides of the lower electrode and the hard mask layer;
defining, by selectively removing the hard mask layer, a space in the second insulating layer to contain a variable resistance layer; and
forming a variable resistance layer in the space to contain a variable resistance layer.

13. The method of claim 12, wherein forming a variable resistance layer:
forming, in the space to contain a variable resistance layer a heat-resistant spacer on the second insulating; and
forming the variable resistance layer on the heat-resistant spacer.

14. The method of claim 13, wherein the heat resistant spacer is formed of silicon nitride.

15. The method of claim 12, wherein a thickness of the first insulating layer is substantially equal to a combined thickness of the lower electrode and the hard mask layer.
